(19) United States
(12) Patent Application Publication
(10) Pub. No.: US 2026/0344382 A1
(43) Pub. Date: Oct. 29, 2026

(54) ISOLATION STRUCTURE AND INTEGRATED CIRCUIT

(71) Applicants: SOUTHEAST UNIVERSITY, Nanjing (CN); CSMC TECHNOLOGIES FAB2 CO., LTD., Wuxi (CN)

(72) Inventors: Long ZHANG, Wuxi (CN); Siyang LIU, Wuxi (CN); Sen ZHANG, Wuxi (CN); Chengwu PAN, Wuxi (CN); Nailong HE, Wuxi (CN); Lihui GU, Wuxi (CN); Weifeng SUN, Wuxi (CN)

(21) Appl. No.: 19/124,164

(22) PCT Filed: Apr. 16, 2024
(86) PCT No.: PCT/CN2024/087925

§ 371 Date: Apr. 24, 2025

(30) Foreign Application Priority Data
Jun. 15, 2023 (CN) 202310714329.3

(51) Int. Cl. H10W 10/50; H10D 64/00; H10D 84/83

(52) U.S. Cl. CPC H10W 10/50; H10D 64/112; H10D 84/835

(57) ABSTRACT

In one aspect, an isolation structure includes: a junction termination including a plurality of junction termination floating field plates; and a lateral double-diffused metal-oxide-semiconductor (LDMOS) field effect transistor including a plurality of LDMOS floating field plates, each of the LDMOS floating field plates being electrically connected to at least one of the junction termination floating field plates, and a length of each of the junction termination floating field plates being greater than a length of the LDMOS floating field plate electrically connected to the junction termination floating field plate.

### CROSS-REFERENCE TO RELATED APPLICATIONS

This application claims priority to Chinese Patent Application No. 2023107143293, entitled “ISOLATION STRUCTURE AND INTEGRATED CIRCUIT” and filed on Jun. 15, 2023, the entire contents of which are incorporated herein by reference.

### TECHNICAL FIELD

The present disclosure relates to the field of semiconductor manufacturing, and in particular to an isolation structure and further to an integrated circuit.

### BACKGROUND

A high-voltage integrated circuit includes a high-voltage semiconductor device and a low-voltage semiconductor device. That is, there is a high-voltage region and a low-voltage region. Therefore, a high-and low-voltage isolation structure is needed to isolate potential between the high-voltage region and the low-voltage region. The isolation structure includes a junction termination, an isolation ring, and a lateral double-diffused metal-oxide-semiconductor (LDMOS) field effect transistor. A LDMOS is a gateway for transmitting electrical signals between the high-voltage region and the low-voltage region, which can easily become a breakdown weak point when subjected to a high voltage. Internal potential thereof is distributed evenly by a technical means, which prevents concentration of potential lines and can increase a breakdown voltage of the LDMOS.

### SUMMARY

According to some embodiments, an isolation structure is provided.

An isolation structure, including: a junction termination including a plurality of junction termination floating field plates; and a LDMOS field effect transistor including a plurality of LDMOS floating field plates, each of the LDMOS floating field plates being electrically connected to at least one of the junction termination floating field plates, and a length of each of the junction termination floating field plates being greater than a length of the LDMOS floating field plate electrically connected thereto. The junction termination floating field plate and the LDMOS floating field plate are made of conductive materials.

The above isolation structure is applicable to an integrated circuit. When devices in the integrated circuit operate, the junction termination floating field plates on the junction termination can form induced potential. Since the LDMOS floating field plate is electrically connected to the junction termination floating field plate, the induced potential may affect potential of the LDMOS field effect transistor through the LDMOS floating field plate. After each junction termination floating field plate induces determined potential on the junction termination and is transferred through the LDMOS floating field plate to the LDMOS field effect transistor, for the LDMOS field effect transistor, each junction termination floating field plate is equivalent to an external “voltage source”, and the potential in the LDMOS field effect transistor may be controlled by the junction termination floating field plate and the LDMOS floating field plate. Therefore, as long as a spacing of each LDMOS floating field plate is controlled, potential distribution within the LDMOS field effect transistor can be indirectly controlled, and the spacing of the LDMOS floating field plate can be flexibly adjusted according to a design requirement. That is, free control over potential inside the LDMOS field effect transistor can be achieved, and potential inside a LDMOS can be distributed evenly, thereby increasing a breakdown voltage of a LDMOS.

In an embodiment, the isolation structure further includes an isolation ring surrounding the LDMOS field effect transistor, the isolation ring being configured to isolate the LDMOS field effect transistor from the junction termination.

In an embodiment, the isolation ring further includes a plurality of isolation ring floating field plates, each of the LDMOS floating field plates being electrically connected to the corresponding junction termination floating field plate through one isolation ring floating field plate, each of the isolation ring floating field plates having one end extending to the corresponding junction termination floating field plate and the other end extending to the corresponding LDMOS floating field plate.

In an embodiment, the LDMOS field effect transistor further includes a source region, a drain region, a gate, a drift region, and a field region insulating layer, at least part of the drift region being located between the source region and the drain region, the field region insulating layer being located on the drift region, the gate having one side close to the source region and the other side close to the drain region, a number of the LDMOS floating field plates being the same as the junction termination floating field plate, the plurality of LDMOS floating field plates being electrically connected to the plurality of junction termination floating field plates in one-to-one correspondence; the LDMOS floating field plates each including a first field plate arranged close to the source region, a second field plate arranged close to the drain region, and a third field plate located between the first field plate and the second field plate, a spacing between adjacent third field plates is less than a2, a spacing between one of the plurality of second field plates that is farthest from the drain region and the adjacent third field plate is greater than a3, a spacing between adjacent second field plates is greater than a3, a spacing between one of the plurality of first field plates that is farthest from the source region and the adjacent third field plate is greater than a4, and a spacing between adjacent first field plates is greater than a4; a2<a3, and a2<a4.

In an embodiment, the LDMOS field effect transistor includes an NLDMOS and a PLDMOS, the isolation ring includes a first isolation ring surrounding the NLDMOS and a second isolation ring surrounding the PLDMOS, and a length of each of the junction termination floating field plates is a sum of a length of the corresponding LDMOS floating field plate of the NLDMOS and a length of the corresponding LDMOS floating field plate of the PLDMOS.

In an embodiment, the junction termination further includes a first insulating layer, and the plurality of junction termination floating field plates are located on the first insulating layer.

In an embodiment, the junction termination further includes a cathode region and an anode region, the cathode region and the anode region being of a same conductivity type as the drain region of the NLDMOS, the cathode region being electrically connected to potential of a source region of the NLDMOS through a metal wire, and the anode region being electrically connected to potential of a drain region of the NLDMOS through a metal wire.

In an embodiment, each of the junction termination floating field plates is connected to the corresponding isolation ring floating field plate and the corresponding LDMOS floating field plate to form a closed ring.

In an embodiment, the isolation ring further includes an isolation junction, a guard well, and a second insulating layer, the plurality of isolation ring floating field plates are located on the second insulating layer, the second insulating layer is located on the isolation junction and the guard well, a conductivity type of the isolation junction and the guard well is opposite to that of the drain region of the NLDMOS, and doping concentration of the guard well is greater than that of the isolation junction.

In an embodiment, each of the isolation ring floating field plate includes a junction termination connecting portion, a LDMOS connecting portion, and a middle portion, one end of the middle portion is connected to the junction termination connecting portion, an angle between the middle portion and an extension line of the junction termination connecting portion on a plane is greater than zero and less than 80 degrees, the other end of the middle portion is connected to the LDMOS connecting portion, and an angle between the middle portion and an extension line of the LDMOS connecting portion on the plane is greater than zero and less than 80 degrees; and the guard well is provided directly below a position where at least part of the junction termination connecting portion is connected to the middle portion, and the guard well is provided directly below a position where at least part of the LDMOS connecting portion is connected to the middle portion.

The guard well includes a strip-shaped doped region arranged at positions where the plurality of junction termination connecting portions are connected to the middle portions, and a strip-shaped doped region arranged at positions where the plurality of LDMOS connecting portions are connected to the middle portions; and/or the guard well includes dot-shaped doped regions arranged in columns at positions where the plurality of junction termination connecting portions are connected to the middle portions, and dot-shaped doped regions arranged in columns at positions where the plurality of LDMOS connecting portions are connected to the middle portions.

In an embodiment, a distance from a position where the junction termination connecting portion is connected to the middle portion to an edge of the isolation ring is b1, and a distance from a position where the LDMOS connecting portion is connected to the middle portion to the edge of the isolation ring is b2, b1 being 10% to 30% of a width of the isolation ring, and b2 being 10% to 30% of the width of the isolation ring.

In an embodiment, the junction termination floating field plate, the isolation ring floating field plate, and the LDMOS floating field plate are made of a same material, and are manufactured and formed in a same manufacturing step.

In an embodiment, the gate is made of a same material as the junction termination floating field plate, the isolation ring floating field plate, and the LDMOS floating field plate, which are manufactured and formed in a same manufacturing step.

In an embodiment, the junction termination floating field plate, the isolation ring floating field plate, and the LDMOS floating field plate are made of doped polysilicon.

In an embodiment, adjacent junction termination floating field plates are equally spaced.

In an embodiment, a spacing between adjacent junction termination floating field plates is al, a2<a1<a3, and a2<a1<a4.

In an embodiment, a spacing between adjacent junction termination floating field plates ranges from 1.0 μm to 3.2 μm, the spacing between adjacent third field plates ranges from 0.5 μm to 3.0 μm, the spacing between adjacent first field plates and the spacing between one of the first field plates that is farthest from the source region and the adjacent third field plate range from 1.2 μm to 4.0 μm, and the spacing between adjacent second field plates and the spacing between one of the second field plates that is farthest from the drain region and the adjacent third field plate range from 1.2 μm to 4.0 μm.

There is also a need to provide an integrated circuit.

An integrated circuit, including a first voltage region, a second voltage region, and an isolation structure located between the first voltage region and the second voltage region, the isolation structure being the isolation structure in any one of the foregoing embodiments.

An operating voltage of a device in the second voltage region is greater than an operating voltage of a device in the first voltage region.

According to the above integrated circuit, when devices in the first voltage region and the second voltage region operate, the junction termination floating field plates on the junction termination can form induced potential. Since the LDMOS floating field plate is electrically connected to the junction termination floating field plate, the induced potential may affect potential of the LDMOS field effect transistor through the LDMOS floating field plate. Since potential lines at a source and a drain of the LDMOS field effect transistor are relatively concentrated, by making the spacing between the first field plates/second field plates arranged close to the source region/drain region wider and the spacing between the third field plates in the middle of the drift region narrower, potential gradient of the LDMOS field effect transistor near the source region/drain region may be decreased and increased near the middle of the drift region, so that the potential distribution of the LDMOS field effect transistor is more uniform, thereby increasing the breakdown voltage of the LDMOS.

In an embodiment, a drain of the NLDMOS is connected to potential of the second voltage region, and a source of the NLDMOS is grounded.

### BRIEF DESCRIPTION OF THE DRAWINGS

In order to better describe and illustrate embodiments and/or examples of those inventions disclosed herein, reference may be made to one or more accompanying drawings. Additional details or examples used to describe the accompanying drawings should not be considered as limitations on the scope of any of the disclosed inventions, the presently described embodiments and/or examples, and the presently understood best mode of these inventions.

FIG. 1 is a front view of an integrated circuit according to an embodiment;

FIG. 2 is a sectional view taken along a line A-A′ in FIG. 1;

FIG. 3 is a sectional view taken along a line B-B′ in FIG. 1;

FIG. 4 is a sectional view taken along a line C-C′ in FIG. 1;

FIG. 5 is a sectional view taken along a line D-D′ in FIG. 1;

FIG. 6 is a sectional view taken along a line E-E′ in FIG. 1;

FIG. 7 is a partial enlarged view of a first isolation ring in FIG. 1;

FIG. 8 is a partial enlarged view near a first isolation ring according to an embodiment;

FIG. 9 is a sectional view taken along the line D-D′ in FIG. 1 in an embodiment with a guard well;

FIG. 10 is a sectional view taken along the line E-E′ in FIG. 1 in an embodiment with a guard well;

FIG. 11 is a sectional view taken along the line D-D′ in FIG. 1 in another embodiment with a guard well;

FIG. 12 is a sectional view taken along the line E-E′ in FIG. 1 in another embodiment with a guard well;

FIG. 13 is a partial enlarged view near the first isolation ring according to another embodiment; and

FIG. 14 is a partial enlarged view near the first isolation ring according to yet another embodiment.

### DETAILED DESCRIPTION

For easy understanding of the present disclosure, a more comprehensive description of the present disclosure is given below with reference to the accompanying drawings. Preferred embodiments of the present disclosure are given in the accompanying drawings. However, the present disclosure may be implemented in many different forms and is not limited to the embodiments described herein. On the contrary, these embodiments are provided to understand the disclosed content of the present disclosure more thoroughly and comprehensively.

Unless otherwise defined, all technical and scientific terms used herein have the same meaning as commonly understood by those skilled in the art to which the present disclosure belongs. The terms used in the specification of the present disclosure are intended only to describe particular embodiments and are not intended to limit the present disclosure. The term “and/or” used herein includes any and all combinations of one or more of the associated listed items.

It should be understood that when an element or layer is referred to as being “on”, “adjacent to”, “connected to”, or “coupled to” another element or layer, the element or layer may be directly on, adjacent to, connected to, or coupled to the another element or layer, or an intervening element or layer may be disposed therebetween. On the contrary, when an element is referred to as being “directly on”, “directly adjacent to”, “directly connected to”, or “directly coupled to” another element or layer, no intervening element or layer may be disposed therebetween. The term “connection” in the specification should be understood as “electrical connection”, “communication connection”, or the like if connected circuits, modules, or units have electrical signal or data transmission therebetween. It should be understood that although terms such as first, second, and third may be used to describe various elements, components, regions, layers, and/or portions, the elements, components, regions, layers, and/or portions may not be limited to such terms. Such terms are used only to distinguish one element, component, region, layer, or portion from another element, component, region, layer, or portion. Thus, without departing from the teaching of the present disclosure, a first element, component, region, layer, or portion may be referred to as a second element, component, region, layer, or portion.

Spatial relationship terms such as “under”, “underneath”, “below”, “beneath”, “over”, and “above” may be used for illustrative purposes to describe a relationship between one element or feature and another element or feature illustrated in the figures. It should be understood that, in addition to the orientations illustrated in the figures, the spatial relationship terms are intended to further include different orientations of the device in use and operation. For example, if the device in the figures is flipped, the element or feature described as “below”, “underneath” or “under” another element or feature may be oriented as “on” the another element or feature. Thus, the exemplary terms “below” and “under” may include two orientations of above and below. In addition, the device may include additional orientations (e.g., 90-degree rotation or other orientations), and thus spatial descriptors used herein may be interpreted accordingly.

The terms used herein are for the purpose of describing particular embodiments only and are not intended to limit the present disclosure. In use, the singular forms of “a”, “one”, and “the” may also include plural forms, unless otherwise clearly specified by the context. It may be understood that “at least one” means one or more, and “a plurality of” means to two or more. “At least part of an element” means part or all of the element. It should be further understood that the terms “composed of” and/or “include,” when used in this specification, specify the presence of the features, integers, steps, operations, elements, and/or components, but may not exclude the presence or addition of one or more of other features, integers, steps, operations, elements, components, and/or groups. In use, the term “and/or” includes any and all combinations of related listed items.

Embodiments of the present disclosure are described herein with reference to cross-sectional views of schematic diagrams of ideal embodiments (and intermediate structures) of the present disclosure. Correspondingly, illustrated shape variations caused by, for example, manufacturing techniques and/or tolerances, may be expected. Thus, the embodiments of the present disclosure may not be limited to the specific shapes of the regions illustrated herein, but may include shape deviations caused by, for example, the manufacturing techniques. For example, an implanted region illustrated as a rectangle, typically, has rounded or curved features and/or a gradient of implant concentration at its edges rather than a binary change from an implanted region to a non-implanted region. Likewise, a buried region formed by implantation may result in some implantation in the region between the buried region and a surface through which the implantation takes place. Thus, the region shown in the drawings is generally schematic, and the illustrated shape is not intended to show the actual shape of the region of the device, and is not intended to limit the scope of the present disclosure.

The semiconductor vocabularies used herein are technical terms commonly used by those skilled in the art. For example, with respect to P-type and N-type impurities, in order to distinguish the doping concentration, a P+type simply represents a P type with heavily doped concentration, a P type represents a P type with medium doped concentration, and a P-type represents a P type with lightly doped concentration. An N+type represents an N type with heavily doped concentration, an N type represents an N type with medium doped concentration, and an N-type represents an N type with lightly doped concentration.

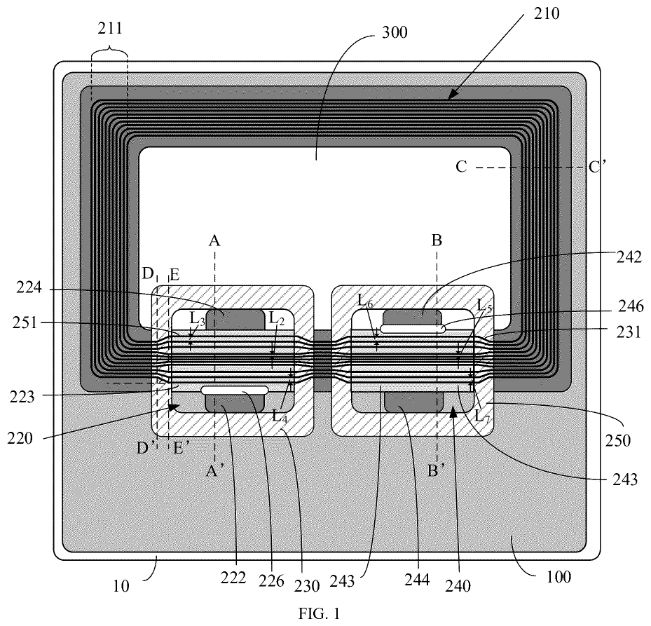

According to some embodiments, a semiconductor high-low voltage isolation structure is provided, which controls potential of a LDMOS in the isolation structure by variable-spacing field plates and can regulate potential distribution and surface electric field distribution in a drift region of the LDMOS, thereby preventing the LDMOS from becoming a breakdown weak point of the isolation structure and obtaining a high-low voltage isolation structure with a better isolation capability. FIG. 1 is a schematic structural diagram of an integrated circuit according to an embodiment, including a low-voltage region 100, a high-voltage region 300, and an isolation structure between the low-voltage region 100 and the high-voltage region 300. An operating voltage of a device in the high-voltage region 300 is greater than an operating voltage of a device in the low-voltage region 100. The isolation structure is configured to isolate potential between the high-voltage region 300 and the low-voltage region 100.

In an embodiment, the isolation structure includes a junction termination 210 and a LDMOS field effect transistor.

The junction termination 210 includes a plurality of junction termination floating field plates 211. The LDMOS field effect transistor includes a plurality of LDMOS floating field plates 251. Each LDMOS floating field plate 251 is electrically connected to at least one junction termination floating field plate 211. A length of each junction termination floating field plate 211 is greater than a length of the LDMOS floating field plate 251 electrically connected thereto. Each junction termination floating field plate 211 and the LDMOS floating field plate 251 are made of conductive materials.

In this embodiment, the plurality of LDMOS floating field plates 251 are electrically connected to the plurality of junction termination floating field plates 211 in one-to-one correspondence. That is, one LDMOS floating field plate 251 is electrically connected to one junction termination floating field plate 211. In other embodiments, alternatively, one junction termination floating field plate 211 is connected to a plurality of LDMOS floating field plates 251. That is, a LDMOS floating field plate 251 electrically connected to a certain junction termination floating field plate 211 is bifurcated into multiple ones in a LDMO region. Alternatively, one LDMOS floating field plate 251 is connected to a plurality of junction termination floating field plates 211. That is, a junction termination floating field plate 211 electrically connected to a LDMOS floating field plate 251 is bifurcated into multiple ones in a junction termination region.

When devices in the integrated circuit (i.e., a low-voltage device in the low-voltage region 100 and a high-voltage device in the high-voltage region 300) operate, the junction termination floating field plates 211 on the junction termination 210 can form induced potential. Since the LDMOS floating field plate 251 is electrically connected to the junction termination floating field plate 211, the induced potential may affect potential of the LDMOS field effect transistor through the LDMOS floating field plate 251. After each junction termination floating field plate 211 induces determined potential on the junction termination 210 and is transferred through the junction termination floating field plate 211 and the LDMOS floating field plate 251 to the LDMOS field effect transistor, for the LDMOS field effect transistor, each junction termination floating field plate 211 is equivalent to an external “voltage source”, and the potential in the LDMOS field effect transistor may be controlled by the junction termination floating field plate 211 and the LDMOS floating field plate 251. Therefore, as long as a spacing of each LDMOS floating field plate 251 is controlled, potential distribution within the LDMOS field effect transistor can be indirectly controlled, and the spacing of the LDMOS floating field plate 251 can be flexibly adjusted according to a design requirement. That is, free control over potential inside the LDMOS field effect transistor can be achieved.

The isolation structure shown in FIG. 1 further includes an isolation ring surrounding the LDMOS field effect transistor, and the isolation ring is configured to isolate the LDMOS field effect transistor from the junction termination 210. The isolation ring is connected to the LDMOS field effect transistor and the junction termination 210. In the embodiment shown in FIG. 1, the isolation ring includes a first isolation ring 230 and a second isolation ring 250, and the LDMOS field effect transistor includes an NLDMOS 220 and a PLDMOS 240. The first isolation ring 230 surrounds the NLDMOS 220, and the second isolation ring 250 surrounds the PLDMOS 240. The floating field plate means that the field plate is not connected to any potential. A main structure of the first isolation ring 230 and the second isolation ring 250 is an isolation junction 233 (see FIG. 5). In an embodiment of the present disclosure, the isolation junction is a P-type doped region.

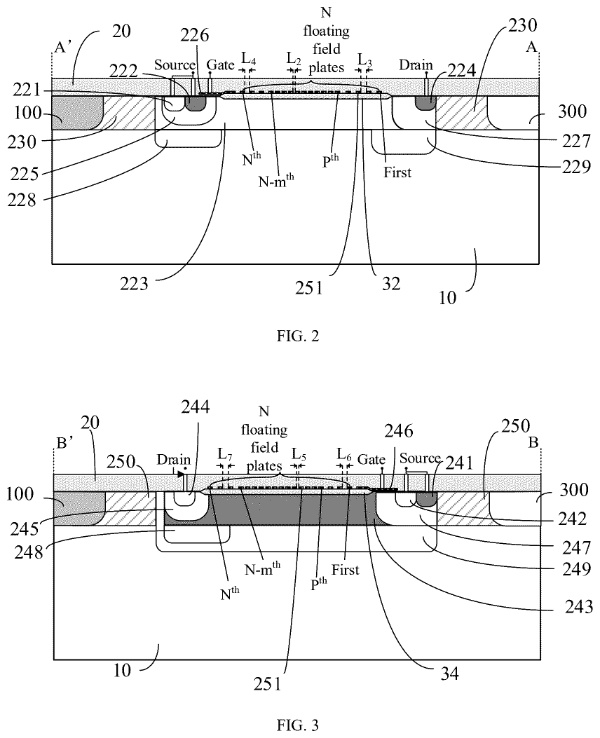

FIG. 2 is a sectional view taken along a line A-A′ in FIG. 1. Referring to FIG. 1 and FIG. 2 together, in an embodiment, the NLDMOS 220 includes a source region 222, a drain region 224, a gate 226, a drift region 223, a field region insulating layer 32, and a LDMOS floating field plate 251. At least part of the drift region 223 is located between the source region 222 and the drain region 224. The field region insulating layer 32 is located on the drift region 223. The gate 226 has one side close to the source region 222 and the other side close to the drain region 224. The source region 222 and the gate 226 are arranged close to the low-voltage region 100, and the drain region 224 is arranged close to the high-voltage region 300. A number of the LDMOS floating field plate 251 is the same as that of the junction termination floating field plate 211. The plurality of LDMOS floating field plates 251 are electrically connected to the plurality of junction termination floating field plates 211 in one-to-one correspondence. Each LDMOS floating field plate 251 includes a first field plate arranged close to the source region 222, a second field plate arranged close to the drain region 224, and a third field plate located between the first field plate and the second field plate. In the embodiments shown in FIG. 1 and FIG. 2, the number of the LDMOS floating field plate 251 is N, and counting from the LDMOS floating field plate 251 closest to the drain region 224, 1^{st} to p-1^{th} ones are second field plates, p^{th} to N-m^{th} ones are third field plates, and N-m+1^{th} and N^{th} ones are first field plates. A spacing between adjacent third field plates is less than a2. A spacing between one (i.e., the p-1^{th} one) of the plurality of second field plates that is farthest from the drain region 224 and the adjacent third field plate (i.e., the p^{th} one) is greater than a3, and a spacing between adjacent second field plates is greater than a3. A spacing between one (i.e., the N-m+1^{th} one) of the plurality of first field plates that is farthest from the source region 222 and the adjacent third field plate (i.e., the N-m^{th} one) is greater than a4, and a spacing between adjacent second field plates is greater than a4. A relationship between a2, a3, and a4 is: a2<a3 and a2<a4. That is, spacings between the first field plates arranged close to the source region 222 and the second field plates arranged close to the drain region 224 are wider, and a spacing between the third field plates in the middle of the drift region 223 is narrower.

FIG. 3 is a sectional view taken along a line B-B′ in FIG. 1. Referring to FIG. 1 and FIG. 3 together, in an embodiment, the PLDMOS 240 includes a source region 242, a drain region 244, a gate 246, a drift region 243, a field region insulating layer 34, and a LDMOS floating field plate 251. At least part of the drift region 243 is located between the source region 242 and the drain region 244. The field region insulating layer 34 is located on the drift region 243. The gate 246 has one side close to the source region 242 and the other side close to the drain region 244. The source region 242 and the gate 246 are arranged close to the low-voltage region 300, and the drain region 244 is arranged close to the high-voltage region 100. A number of the LDMOS floating field plate 251 is the same as that of the junction termination floating field plate 211. The plurality of LDMOS floating field plates 251 are electrically connected to the plurality of junction termination floating field plates 211 in one-to-one correspondence. Each LDMOS floating field plate 251 includes a first field plate arranged close to the source region 242, a second field plate arranged close to the drain region 244, and a third field plate located between the first field plate and the second field plate. In the embodiments shown in FIG. 1 and FIG. 3, the number of the LDMOS floating field plate 251 is N, and counting from the LDMOS floating field plate 251 closest to the sour region 244, 1^{st} to p-1^{th} ones are first field plates, p^{th} to N-m^{th} ones are third field plates, and N-m+1^{th} and N^{th} ones are second field plates. A spacing between adjacent third field plates is less than a2, a spacing between one (i.e., the N-m+1^{th} one) of the plurality of second field plates that is farthest from the sour region 224 and the adjacent third field plate (i.e., the N-m^{th} one) is greater than a3, a spacing between adjacent second field plates is greater than a3, a spacing between one (i.e., the p-1^{th} one) of the plurality of first field plates that is farthest from the drain region 224 and the adjacent third field plate (i.e., the p^{th} one) is greater than a4, and a spacing between adjacent first field plates is greater than a4. Then, a relationship between a2, a3, and a4 is: a2<a3 and a2<a4. That is, spacings between the first field plates arranged close to the source region 242 and the second field plates arranged close to the drain region 244 are wider, and a spacing between the third field plates in the middle of the drift region 243 is narrower.

A length of each junction termination floating field plate 211 is greater than a length of the corresponding LDMOS floating field plate, to ensure that potential of the junction termination floating field plate 211 dominates. Taking FIG. 1 as an example, the length of each junction termination floating field plate 211 is greater than a sum of a length of the corresponding LDMOS floating field plate 251 of the NLDMOS 220 and a length of the corresponding LDMOS floating field plate 251 of the PLDMOS 240.

Since potential lines at a source and a drain of the LDMOS field effect transistor are relatively concentrated, by making the spacings between the first field plates/second field plates arranged close to the source region/drain region wider and the spacing between the third field plates in the middle of the drift region narrower, potential gradient of the LDMOS field effect transistor near the source region/drain region may be decreased and increased near the middle of the drift region, so that the potential distribution of the LDMOS field effect transistor is more uniform, thereby increasing the breakdown voltage of the LDMOS in the isolation structure.

In the embodiment shown in FIG. 1, the isolation ring further includes a plurality of isolation ring floating field plates 231 whose number is the same as that of the junction termination floating field plates 211. The junction termination floating field plates 211 are electrically connected to the corresponding LDMOS floating field plates 251 in one-to-one correspondence through the corresponding isolation ring floating field plates 231. Each isolation ring floating field plate 231 has one end extending to the corresponding junction termination floating field plate 211 and the other end extending to the corresponding LDMOS floating field plate 251.

In an embodiment, a spacing between adjacent junction termination floating field plates is a1, a2<a1<a3, and a2<a1<a4. On the basis of the fact that the above conditions a2<a1<a3 and a2<a1<a4 are satisfied, a spacing between adjacent junction termination floating field plates 211 ranges from 1.0 μm to 3.2 μm, the spacing between adjacent third field plates ranges from 0.5 μm to 3.0 μm, the spacing between adjacent first field plates and the spacing between one of the first field plates that is farthest from the source region and the adjacent third field plate range from 1.2 μm to 4.0 μm, and the spacing between adjacent second field plates and the spacing between one of the second field plates that is farthest from the drain region and the adjacent third field plate range from 1.2 μm to 4.0 μm.

In an embodiment of the present disclosure, adjacent junction termination floating field plates 211 are equally spaced at a spacing L₁. In the NLDMOS 220, the first to p^{th} LDMOS floating field plates 251 close to the drain region 224 are equally spaced at a spacing L₃, the N-m^{th} to N^{th} LDMOS floating field plates 251 close to the source region 222 are equally spaced at a spacing L₄, and the remaining p^{th} to N-m^{th} LDMOS floating field plates 251 are equally spaced at a spacing L₂. In the PLDMOS 240, the first to p^{th} LDMOS floating field plates 251 close to the drain region 242 are equally spaced at a spacing L₆, the N-m^{th} to Nₜₕ LDMOS floating field plates 251 close to the source region 244 are equally spaced at a spacing L₇, and the remaining p^{th} to N-m^{th} LDMOS floating field plates 251 are equally spaced at a spacing L₅. Moreover, the following relationships are satisfied: L₁>L₂, L₁>L₅, L₃>L₁, L₄>L₁, L₆>L₁, and L₇>L₁.

In an embodiment, a total number N of the plurality of floating field plates ranges from 10 to 100, p and m range from 2 to 15, and N-p-m ranges from 1 to 96.

In an embodiment, the source region 222 and the drain region 224 of the NLDMOS 220 are N+regions, and the drift region 223 is an N-type drift region. The source region 242 and the drain region 244 of the PLDMOS 240 are P+regions, and the drift region 243 is a P-type drift region.

In the embodiment shown in FIG. 2, the NLDMOS 220 further includes a body region 221, a P well 225, an N well 227, a deep N well 229, and a P-type buried layer 228. The body region 221 and the source region 222 are led out through a contact hole and then short-circuited. The body region 221 and the source region 222 are located in the P well 225. The drain region 224 is located in the N well 227. The field region insulating layer 32 of the NLDMOS 220 is located between the source region 222 and the drain region 224. The P-type buried layer 228 is located below the drift region 223 and the P well 225. The deep N well 229 is located below the drift region 223 and the N well 227.

In the embodiment shown in FIG. 3, the PLDMOS 240 further includes a body region 241, a P well 225, an N well 247, a deep N well 249, and a P-type buried layer 248. The body region 241 and the source region 242 are led out through contact holes and then short-circuited. The body region 241 and the source region 242 are located in the P well 247. The drain region 244 is located in the N well 245. The field region insulating layer 34 of the PLDMOS 240 is located between the source region 242 and the drain region 244. The deep N well 249 is located below the drift region 243 and the N well 247. The P-type buried layer 248 is located in the deep N well 249 and below the drift region 243 and the P well 245.

In an embodiment, a drain of the NLDMOS 220 is connected to potential of the high-voltage region 300, and a source of the NLDMOS 220 is grounded. In an embodiment, a source of the PLDMOS 240 is connected to potential of the high-voltage region 300, and a drain of the PLDMOS 240 is grounded.

In an embodiment, an isolation structure (including a junction termination 210, an isolation ring, and a LDMOS field effect transistor) further includes a substrate 10 at the bottom and a passivation layer 20 located on an upper surface of the device. In the embodiment shown in FIG. 1, the substrate 10 is made of P-type doped monocrystalline silicon.

In an embodiment, the junction termination floating field plate 211, the isolation ring floating field plate 231, and the LDMOS floating field plate 251 are made of a same material, and are manufactured and formed in a same manufacturing step. In an embodiment, the junction termination floating field plate 211, the isolation ring floating field plate 231, and the LDMOS floating field plate 251 are made of doped polysilicon. In an embodiment, the gate in the LDMOS field effect transistor (including the NLDMOS 220 and the PLDMOS 240) is made of doped polysilicon. In an embodiment, the junction termination floating field plate 211, the isolation ring floating field plate 231, the LDMOS floating field plate 251, the gate 226, and the gate 246 may be manufactured and formed in a same manufacturing step.

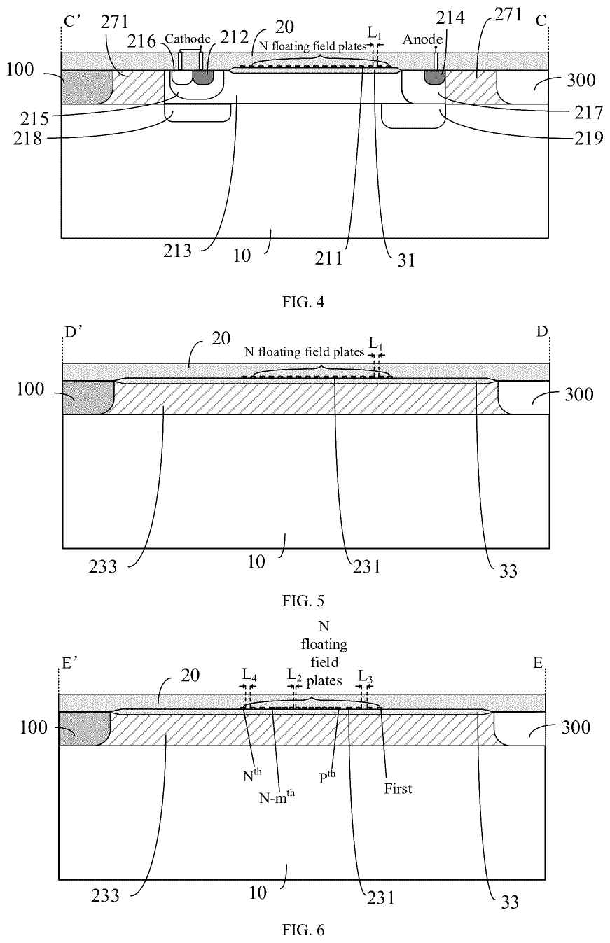

FIG. 4 is a sectional view taken along a line C-C′ in FIG. 1. Referring to FIG. 1 and FIG. 4 together, in an embodiment, the junction termination 210 further includes a first insulating layer 31, and each junction termination floating field plate 211 is located on the first insulating layer 31.

In an embodiment, the first insulating layer 31, the field region insulating layer 32, and the field region insulating layer 34 may be made of silicon oxide, such as silicon dioxide.

In the embodiment shown in FIG. 4, the junction termination 210 further includes a cathode region 212 and an anode region 214. The cathode region 212 and the anode region 214 are of a same conductivity type as the drain region 224 of the NLDMOS 220. That is, both are N+regions. The cathode region 212 is electrically connected to potential of a source region 222 of the NLDMOS 220 through a metal wire (not shown) led out through the contact hole, and the anode region 214 is electrically connected to potential of a drain region 224 of the NLDMOS 220 through a metal wire (not shown) led out through the contact hole. A structure similar to an NLDMOS without a gate is arranged in the junction termination 210, which helps achieve isolation between the high-voltage region 300 and the low-voltage region 100.

In the embodiment shown in FIG. 4, the junction termination 210 further includes an N-type region 213. At least part of the N-type region 213 is located between the cathode region 212 and the anode region 214. The first insulating layer 31 is located on the N-type region 213. The N-type region 213 functions similarly to the drift region.

In the embodiment shown in FIG. 4, the junction termination 210 further includes a termination isolation junction 271. The termination isolation junction 271 is located between the N-type region 213 and the low-voltage region 100 and between the N-type region 213 and the high-voltage region 300. The termination isolation junction 271 has a same conductivity type as the substrate 10. In an embodiment where the substrate 10 is a P-type substrate, the termination isolation junction 271 is a P-type doped region.

In an embodiment, the junction termination 210 further includes a body region 216, a P well 215, an N well 217, a deep N well 219, and a P-type buried layer 218. The body region 216 and the cathode region 212 are led out through a contact hole and then short-circuited. The body region 216 and the cathode region 212 are located in the P well 215. The anode region 214 is located in the N well 217. The first insulating layer 31 is located between the P well 215 and the N well 217. The P-type buried layer 218 is located below the N-type region 213 and the P well 215. The deep N well 219 is located below the N-type region 213 and the N well 217.

Referring to FIG. 1, in an embodiment, each junction termination floating field plate 211 is connected to the corresponding isolation ring floating field plate 231 and the corresponding LDMOS floating field plate 251 to form a closed ring, that is, a closed floating field plate. It may be understood that the floating field plates start from the junction termination 210, cross the isolation ring, are transferred to the NLDMOS 220 and the PLDMOS 240, and are connected end to end. N floating field plates on the junction termination 210 are equally spaced at a spacing L₁. When devices in the high-voltage region 300 and the low-voltage region 100 start to operate, potential between the high-voltage region 300 and the low-voltage region 100 is isolated by the isolation structure. In this case, a drain end (i.e., the anode region 214) and a source end (i.e., the cathode region 212) of the junction termination 210, a source end and a drain end of the PLDMOS 240, and a drain end and a source end of the NLDMOS 220 are subjected to a voltage between the high-voltage region 300 and the low-voltage region 100, and the potential decreases from high-voltage potential to ground potential inside the junction termination 210, the NLDMOS 220, and the PLDMOS 240. Since the floating field plate is a highly doped polysilicon field plate with a large number of free electrons therein, the floating field plate may carry certain induced potential in an electric field. N junction termination floating field plates 211 on the junction termination 210 may be affected by potential distribution within the junction termination 210 and induce potential V₁, V₂, . . . , and V_{N} respectively. A value of the induced potential carried in each floating field plate is determined by its position and is almost equal to potential of a junction termination region therebelow. Therefore, the potential distribution within the junction termination 210 controls the induced potential carried in each junction termination floating field plate 211. After the floating field plate is transferred to the NLDMOS 220 and the PLDMOS 240, the potential distribution within the NLDMOS 220 and the PLDMOS 240 may also affect the induced potential of the floating field plate. In the isolation structure, an area occupied by the junction termination 210 is much larger than an area occupied by the LDMOS. Correspondingly, junction termination regions that each closed floating field plate passes through are also much more than regions that the LDMOS passes through (refer to FIG. 1), and each closed floating field plate can only carry determined induced potential. That is, each closed floating field plate is an equipotential body in the electric field. Therefore, the potential distribution within the junction termination 210 is absolutely dominant to the induced potential generated by the closed floating field plate, which may be regarded that the induced potential carried in each closed floating field plate is determined by the junction termination 210. Since the LDMOS is not sufficient to change the induced potential of each closed floating field plate, each field plate extending from the junction termination 210 is equivalent to an external “voltage source” for the LDMOS, and the floating field plate forces a partial region of the LDMOS therebelow to approach the potential of the floating field plate.

In summary, the semiconductor high-low voltage isolation structure proposed in the above embodiments forms potential control system with floating field plates. The potential distribution within the junction termination 210 controls the induced potential carried in the closed floating field plate, and the induced potential carried in the closed floating field plate controls potential distribution within the LDMOS.

According to the above principle, in the above embodiments, potential control over the LDMOS in the isolation structure is realized based on variable-spacing floating field plates. Firstly, potential distribution within the NLDMOS 220 and the PLDMOS 240 approximates that within the junction termination 210. If two adjacent field plates in N floating field plates are transferred to a LDMOS region with an equal spacing L₁ everywhere, the potential distribution within the LDMOS is clamped by the floating field plate and therefore approximates the potential distribution within the junction termination 210. Then, by changing the spacing of the LDMOS floating field plate 251 on the LDMOS, the potential distribution within the LDMOS is further controlled according to a requirement, and magnitude of electric field intensity in different regions in the LDMOS is changed. In the present disclosure, by using variable-spacing field plates, N junction termination floating field plates 211 originally equally spaced at L₁ on the junction termination 210 are “transformed” on the isolation ring in the form of inclined field plates. Then, the N floating field plates may be distributed on the LDMOS at a spacing different from L₁. Each floating field plate has determined potential before being transferred to the LDMOS region, so a potential difference therebetween is also determined. Changing the spacing of the field plates means changing a gradient of the potential therebetween. Correspondingly, a gradient of the potential of the LDMOS region covered by the LDMOS floating field plates 251 with variable spacings may also change. Moreover, electric field intensity is the gradient of the potential. Therefore, changing the spacing of the LDMOS floating field plates 251 in a certain region is to change the electric field intensity of the corresponding region, thereby realizing control over internal potential and surface electric field intensity of the LDMOS.

That is, the variable-spacing field plate is intended to control the potential distribution of the LDMOS with the potential distribution of the junction termination 210, thereby improving performance of the LDMOS. Therefore, an isolation capability of the entire isolation structure has also been improved, and the closed floating field plate is an external control for its benefit device LDMOS. Compared with the traditional field plate technology, in the present disclosure, potential line concentration point can be eliminated, and the variable-spacing field plate can control the gradient of the potential of each part of the drift region of the LDMOS to be almost equal, which means that the potential changes uniformly and does not change sharply in some regions. Therefore, the LDMOS may not become a breakdown weak point of the isolation structure. In the present disclosure, the control over the potential within the LDMOS is comprehensive, and the variable-spacing field plate can realize the potential control over the entire drift region of the LDMOS, rather than being limited to part of the region. On the other hand, the solution may not lead to process and structural complication. That is, an increase in manufacturing costs is prevented. The closed floating field plate in the above embodiments may be a polysilicon field plate. A polysilicon process is a common process for forming gates of each type of devices in a manufacturing process of a high-low voltage isolation structure. Therefore, the closed floating field plate can be formed in a same process with polysilicon gates without increasing the manufacturing process. In addition, the closed floating field plate does not need to change the internal structure when controlling the potential of the LDMOS, thereby also preventing design and manufacturing complication of the LDMOS.

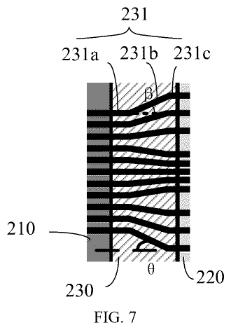

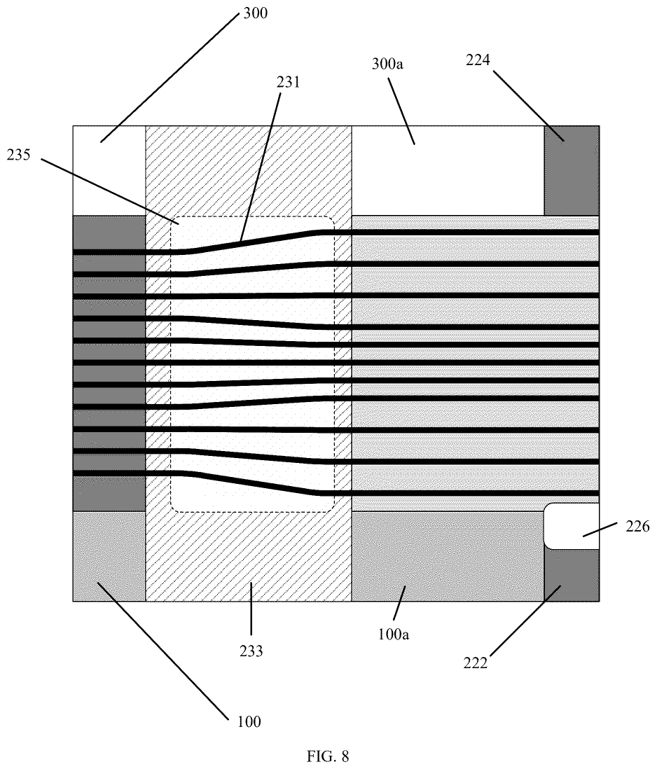

FIG. 5 is a sectional view taken along a line D-D′ in FIG. 1, FIG. 6 is a sectional view taken along a line E-E′ in FIG. 1, and FIG. 7 is a partial enlarged view of the first isolation ring 230 in FIG. 1. In an embodiment, the isolation ring further includes a second insulating layer 33, each isolation ring floating field plate 231 is located on the second insulating layer 33, and the second insulating layer 33 is located on the isolation junction 233. In an embodiment, the second insulating layer 33 may be made of silicon oxide, such as silicon dioxide. The isolation junction 233 has a same conductivity type as the substrate 10. In an embodiment where the substrate 10 is a P-type substrate, the isolation junction 233 is a P-type doped region.

Referring to FIG. 7, each isolation ring floating field plate 231 includes a junction termination connecting portion 231a, a LDMOS connecting portion 231c, and a middle portion 231b. One end of the middle portion 231b is connected to the junction termination connecting portion 231a, and an angle β between the middle portion 231b and an extension line of the junction termination connecting portion 231 a on a plane is greater than zero and less than 80 degrees. The other end of the middle portion 231b is connected to the LDMOS connecting portion 231c, and an angle 0 between the middle portion 231b and an extension line of the LDMOS connecting portion 231c on the plane is greater than zero and less than 80 degrees For the closed floating field plate, in order to make the potential distribution on the LDMOS field effect transistor in the isolation structure more uniform, the spacing between adjacent LDMOS floating field plates 251 is inconsistent with the spacing between adjacent junction termination floating field plates 211. “Transformation” is performed by taking the form of inclined field plates on the isolation ring, so as to change the spacing of the floating field plates from the junction termination floating field plates 211 to spacing distribution of the LDMOS floating field plates 251.

In an embodiment, a distance from a position where the junction termination connecting portion 231a is connected to the middle portion 231b to an edge of the isolation ring is b1, a distance from a position where the LDMOS connecting portion 231c is connected to the middle portion 231 a to the edge of the isolation ring is b 2, b 1 is 10% to 30% of a width of the isolation ring, and b2 is 10% to 30% of the width of the isolation ring. That is, the position where the middle portion 231b is connected to the junction termination connecting portion 231a/the LDMOS connecting portion 231c should be kept at a certain distance from a boundary of the isolation ring. This is because corners (i.e., positions at the angles β and θ) of the inclined field plate may lead to concentration of power lines, thereby generating a strong electric field. The arrangement that the corners are at a certain distance from the boundary of the isolation ring can increase a withstand voltage of the isolation ring (i.e., increase a breakdown voltage) compared to the arrangement that the corners are at the boundary of the isolation ring, which prevents punch-through between the LDMOS field effect transistor and the junction termination 210. In the embodiment shown in FIG. 7, the corners of the inclined field plate are arranged at positions of the line D-D′ and the line E-E′.

In an embodiment, the isolation ring further includes a guard well 235, and the second insulating layer 33 is locate on the isolation junction 233 and the guard well 235. A conductivity type of the guard well 235 is opposite to that of the drain region 222 of the NLDMOS, and doping concentration of the guard well 235 is greater than that of the isolation junction 233. In an embodiment, the guard well 235 is a P+ doped region. Through the arrangement of the guard well 235, the withstand voltage of the isolation ring can be further increased to prevent breakdown of the isolation ring caused by concentration of potential lines. In an embodiment, the guard well 235 is provided directly below a position where at least part of the junction termination connecting portion 231a is connected to the middle portion 231b, and the guard well 235 is provided directly below a position where at least part of the LDMOS connecting portion 231c is connected to the middle portion 231b. This is because the corners of the inclined field plate may lead to concentration of power lines. Therefore, the arrangement that the guard well 235 is directly below the corners of the inclined field plate can achieve a better effect of increasing the withstand voltage of the isolation ring.

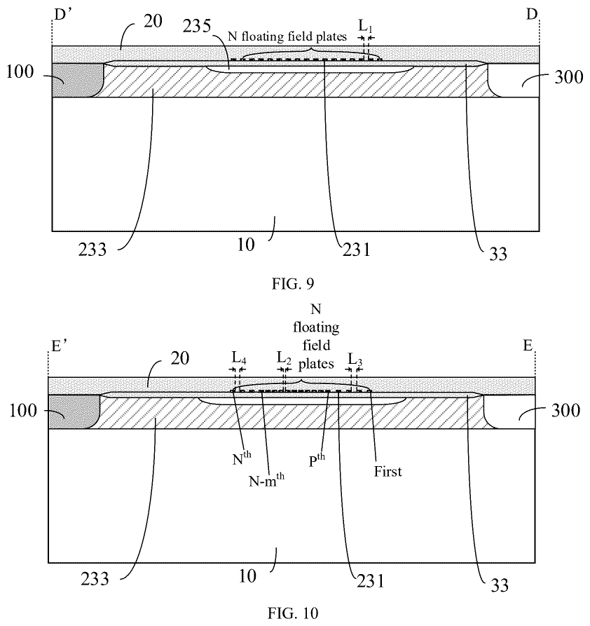

FIG. 8 is a partial enlarged view of the isolation structure near the first isolation ring 230 according to an embodiment, in which the guard well 235 is translucent. In the embodiment, the guard well 235 is an integral P+ structure. For the solution of forming the guard well 235 by using an ion implantation process, in an embodiment, a width of an implantation window of the guard well 235 should be 100% to 110% of a distance between two ends of the inclined field plate, and the length should be 100% to 110% of a maximum distance between the first field plate and the Nth field plate, to be laid below the corners of all the inclined field plates. In FIG. 8, a region 100a has a same structure as part of the low-voltage region 100, and a region 300a has a same structure as part of the high-voltage region 300. FIG. 9 is a sectional view taken along the line D-D′ in FIG. 1 in an embodiment with the guard well 235, and FIG. 10 is a sectional view taken along the line E-E′ in FIG. 1 in an embodiment with the guard well 235. Compared with the embodiment shown in FIG. 5 and the embodiment shown in FIG. 6 respectively, the guard well 235 is added in FIG. 9 and FIG. 10.

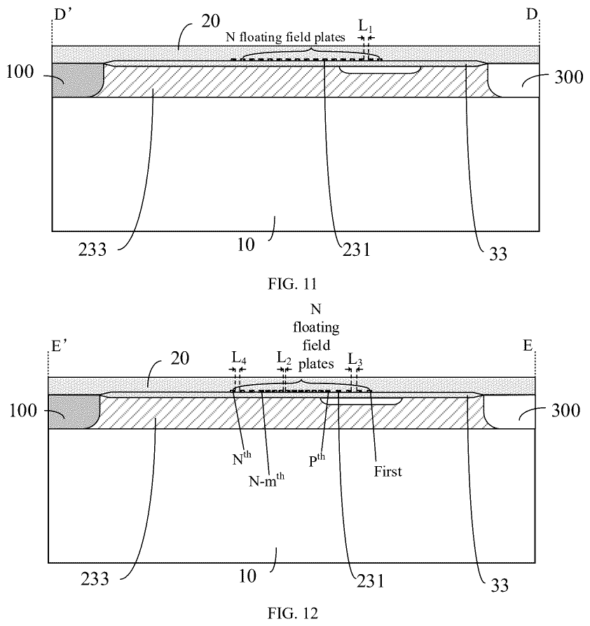

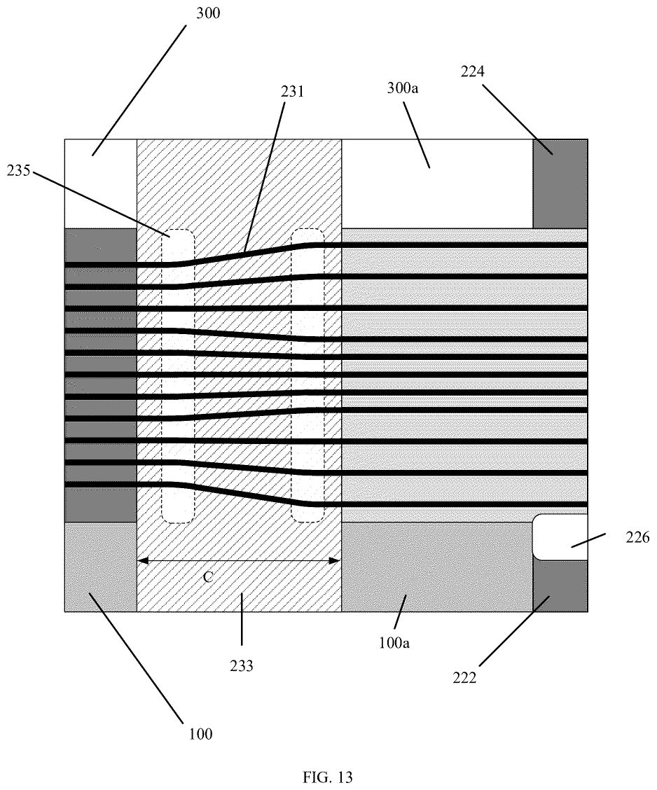

In some embodiments, the guard well 235 may also only act on part of the isolation ring floating field plate 231, for example, only act on a high-voltage side field plate, referring to FIG. 11 and FIG. 12. In the embodiments shown in FIG. 11 and FIG. 12, the guard well 235 is arranged below part of the isolation ring floating field plates 231 close to the high-voltage region 300, and no guard well 235 is arranged below the remaining isolation ring floating field plates 231. In the embodiment shown in FIG. 12, the guard well 235 is arranged below a plurality of isolation ring floating field plates 231 at a spacing L₃ (i.e., the first to p^{th} isolation ring floating field plates 231 close to the high-voltage region 300). In some embodiments, a length of the guard well 235 is 100% to 110% of a maximum distance from the first to p^{th} field plates. For an embodiment where the guard well 235 is arranged only below part of the isolation ring floating field plates 231, isolation ring floating field plates 231 on which the guard well 235 acts are selected as several isolation ring floating field plates 231 close to the high-voltage region 300, which can achieve a better effect of increasing the withstand voltage of the isolation ring. In other embodiments, the isolation ring floating field plates 231 may be arranged below other isolation ring floating field plates 231.

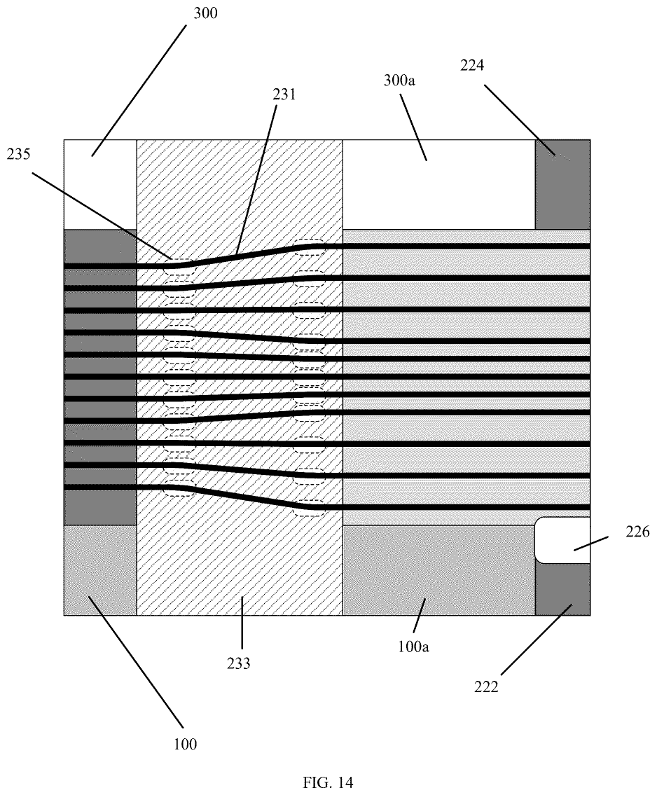

FIG. 13 is a partial enlarged view near the first isolation ring 230 according to another embodiment, in which the guard wells 235 are translucent. A main difference from the embodiment shown in FIG. 8 is that the guard wells 235 are strip-shaped P+type doped regions arranged at corners. For the solution of forming the guard well 235 by using an ion implantation process, in an embodiment, a width of an implantation window of the guard well 235 should be 2% to 5% of a width of the isolation ring, and the length should be 100% to 110% of a maximum distance between the first field plate and the N^{th} field plate, to be laid below the corners of all the inclined field plates.

FIG. 14 is a partial enlarged view near the first isolation ring 230 according to yet another embodiment, in which the guard wells 235 are translucent. A main difference from the embodiment shown in FIG. 8 is that the guard wells 235 are dot-shaped P+type doped regions arranged at corners, and the dot-shaped P+type doped regions are arranged in columns. For the solution of forming the guard well 235 by using an ion implantation process, in an embodiment, a width of an implantation window of the guard well 235 should be 2% to 5% of a width of the isolation ring.

In an embodiment, P+implantation in the guard well 235, the junction termination 210, and the LDMOS field effect transistor are same implantation. That is, implantation lithography prior to ion implantation of the guard well 235 use a same photolithography mask as the body region 221 of the NLDMOS 220, the source region 242 and the drain region 244 of the PLDMOS 240, and the body region 216 of the junction termination 210, and lithography of an implantation window is completed in a same lithography step. Therefore, the formation of the guard well 235 may not increase manufacturing processes, which helps save the cost.

In the description of this specification, the description with reference to the terms “some embodiments,” “other embodiments,” “ideal embodiments,” and the like in the description means that a particular feature, structure, material, or characteristic described in connection with the embodiment or example is included in at least one embodiment or example of the present disclosure. In this specification, exemplary descriptions of the above terms are not necessarily referring to the same embodiment or example.

The technical features in the above embodiments may be randomly combined. For concise description, not all possible combinations of the technical features in the above embodiments are described. However, all the combinations of the technical features are to be considered as falling within the scope described in this specification provided that they do not conflict with each other.

The above embodiments only describe several implementations of the present disclosure, and their description is specific and detailed, but cannot therefore be understood as a limitation on the patent scope of the present disclosure. It should be noted that those of ordinary skill in the art may further make variations and improvements without departing from the conception of the present disclosure, and these all fall within the protection scope of the present disclosure. Therefore, the patent protection scope of the present disclosure should be subject to the appended claims.

1. An isolation structure, comprising:
a junction termination comprising a plurality of junction termination floating field plates;
a lateral double-diffused metal-oxide-semiconductor (LDMOS) field effect transistor comprising a plurality of LDMOS floating field plates, each of the LDMOS floating field plates being electrically connected to at least one of the junction termination floating field plates, and a length of each of the junction termination floating field plates being greater than a length of the LDMOS floating field plate electrically connected to the junction termination floating field plate.

2. The isolation structure according to claim 1, further comprising an isolation ring surrounding the LDMOS field effect transistor, the isolation ring being configured to isolate the LDMOS field effect transistor from the junction termination.

3. The isolation structure according to claim 2, wherein the isolation ring further comprises a plurality of isolation ring floating field plates, each of the LDMOS floating field plates being electrically connected to the corresponding junction termination floating field plate through one isolation ring floating field plate, one end of each of the isolation ring floating field plates extending to the corresponding junction termination floating field plate, and the other end of the isolation ring floating field plate extending to the corresponding LDMOS floating field plate.

4. The isolation structure according to claim 3, wherein the LDMOS field effect transistor further comprises a source region, a drain region, a gate, a drift region, and a field region insulating layer, at least part of the drift region being located between the source region and the drain region, the field region insulating layer being located on the drift region, the gate having one side close to the source region and the other side close to the drain region, a number of the LDMOS floating field plates being the same as the junction termination floating field plate, the plurality of LDMOS floating field plates being electrically connected to the plurality of junction termination floating field plates in one-to-one correspondence; the LDMOS floating field plates each comprising a first field plate arranged close to the source region, a second field plate arranged close to the drain region, and a third field plate located between the first field plate and the second field plate, a spacing between adjacent third field plates is less than a2, a spacing between one of the plurality of second field plates that is farthest from the drain region and the adjacent third field plate is greater than a3, a spacing between adjacent second field plates is greater than a3, a spacing between one of the plurality of first field plates that is farthest from the source region and the adjacent third field plate is greater than a4, and a spacing between adjacent first field plates is greater than a4; a2<a3, and a2<a4.

5. The isolation structure according to claim 4, wherein the LDMOS field effect transistor comprises an NLDMOS and a PLDMOS, the isolation ring comprises a first isolation ring surrounding the NLDMOS and a second isolation ring surrounding the PLDMOS, and a length of each of the junction termination floating field plates is a sum of a length of the corresponding LDMOS floating field plate of the NLDMOS and a length of the corresponding LDMOS floating field plate of the PLDMOS.

6. The isolation structure according to claim 5, wherein the junction termination further comprises a first insulating layer, and the plurality of junction termination floating field plates are located on the first insulating layer.

7. The isolation structure according to claim 6, wherein the junction termination further comprises a cathode region and an anode region, the cathode region and the anode region being N-type regions, the cathode region being electrically connected to potential of a source region of the NLDMOS through a metal wire, and the anode region being electrically connected to potential of a drain region of the NLDMOS through a metal wire.

8. The isolation structure according to claim 3, wherein each of the junction termination floating field plates is connected to the corresponding isolation ring floating field plate and the corresponding LDMOS floating field plate to form a closed ring.

9. The isolation structure according to claim 7, wherein the isolation ring further comprises an isolation junction, a guard well, and a second insulating layer, the plurality of isolation ring floating field plates are located on the second insulating layer, the second insulating layer is located on the isolation junction and the guard well, the isolation junction and the guard well are P-type regions, and doping concentration of the guard well is greater than that of the isolation junction; and
each of the isolation ring floating field plate comprises a junction termination connecting portion, a LDMOS connecting portion, and a middle portion, one end of the middle portion is connected to the junction termination connecting portion, an angle between the middle portion and an extension line of the junction termination connecting portion on a plane is greater than zero and less than 80 degrees, the other end of the middle portion is connected to the LDMOS connecting portion, and an angle between the middle portion and an extension line of the LDMOS connecting portion on the plane is greater than zero and less than 80 degrees; and the guard well is provided directly below a position where at least part of the junction termination connecting portion is connected to the middle portion, and the guard well is provided directly below a position where at least part of the LDMOS connecting portion is connected to the middle portion.

10. The isolation structure according to claim 9, wherein the guard well comprises a strip-shaped doped region arranged at positions where the plurality of junction termination connecting portions are connected to the middle portions, and a strip-shaped doped region arranged at positions where the plurality of LDMOS connecting portions are connected to the middle portions.

11. The isolation structure according to claim 9, wherein the guard well comprises dot-shaped doped regions arranged in columns at positions where the plurality of junction termination connecting portions are connected to the middle portions, and dot-shaped doped regions arranged in columns at positions where the plurality of LDMOS connecting portions are connected to the middle portions.

12. The isolation structure according to claim 9, wherein a distance from a position where the junction termination connecting portion is connected to the middle portion to an edge of the isolation ring is b1, and a distance from a position where the LDMOS connecting portion is connected to the middle portion to the edge of the isolation ring is b 2, b1 being 10% to 30% of a width of the isolation ring, and b2 being 10% to 30% of the width of the isolation ring.

13. The isolation structure according to claim 3, wherein the junction termination floating field plate, the isolation ring floating field plate, and the LDMOS floating field plate are made of a same material.

14. The isolation structure according to claim 13, wherein the junction termination floating field plate, the isolation ring floating field plate, and the LDMOS floating field plate are made of doped polysilicon.

15. The isolation structure according to claim 4, wherein the gate is made of a same material as the junction termination floating field plate, the isolation ring floating field plate, and the LDMOS floating field plate.

16. The isolation structure according to claim 4, wherein a spacing between adjacent junction termination floating field plates is a1, a2<a1<a3, and a2<a1<a4.

17. The isolation structure according to claim 4, wherein adjacent junction termination floating field plates are equally spaced.

18. The isolation structure according to claim 4, wherein a spacing between adjacent junction termination floating field plates ranges from 1.0 μm to 3.2 μm, the spacing between adjacent third field plates ranges from 0.5 μm to 3.0 μm, the spacing between adjacent first field plates and the spacing between one of the first field plates that is farthest from the source region and the adjacent third field plate range from 1.2 μm to 4.0 μm, and the spacing between adjacent second field plates and the spacing between one of the second field plates that is farthest from the drain region and the adjacent third field plate range from 1.2 μm to 4.0 μm.

19. An integrated circuit, comprising a first voltage region, a second voltage region, and the isolation structure according to claim 1 located between the first voltage region and the second voltage region.

20. The integrated circuit according to claim 19, wherein an operating voltage of a device in the second voltage region is greater than an operating voltage of a device in the first voltage region.
